(19) United States
(12) Patent Application Publication
(10) Pub. No.: US 2025/0116719 A1
(43) Pub. Date: Apr. 10, 2025

(54) Method and System of Determining Reference Internal Impedance of Battery

(71) Applicant: Richtek Technology Corporation, Hsinchu (TW)

(72) Inventors: Chieh-En Chen, Hsinchu (TW); Fu-Chi Lin, Hsinchu (TW); Wen-Yuan Li, Hsinchu (TW)

(21) Appl. No.: 18/889,416

(22) Filed: Sep. 19, 2024

Related U.S. Application Data
(60) Provisional application No. 63/589,311, filed on Oct. 10, 2023.

(30) Foreign Application Priority Data
Aug. 30, 2024 (TW) 113132838

(51) Int. Cl. G01R 31/389; G01R 31/367; G01R 31/388; H01M 10/48

(52) U.S. Cl. CPC G01R 31/389; G01R 31/367; G01R 31/388; H01M 10/486

(57) ABSTRACT

A method for determining the reference internal impedance of a battery includes the following steps: (a) during a sensing period, sensing a battery voltage, a battery current flowing through the battery, and a battery temperature to obtain a sensing result, thereby determining a depth of discharge (DOD); (b) in step (a), comparing the sensing result with a predetermined threshold to determine whether to accept the sensing result; (c) when the sensing result is accepted, calculating a corresponding battery internal impedance based on the sensing result and the depth of discharge; (d) performing regression analysis on the battery internal impedance and a plurality of previous battery internal impedances to obtain a moving average battery internal impedance corresponding to the depth of discharge; and (e) obtaining a corresponding reference battery internal impedance based on the moving average battery internal impedance.

### CROSS REFERENCE

The present invention claims priority to US 63/589311 filed on Oct. 10, 2023 and claims priority to TW 113132838 filed on Aug. 30, 2024.

### BACKGROUND OF THE INVENTION

### Field of Invention

The present invention relates to a method of determining a reference internal impedance of a battery; particularly, it relates to such method by obtaining a moving average battery internal impedance through regression analysis. The present invention also relates to a system of determining a reference internal impedance of a battery.

### Description of Related Art

In prior art methods and systems of determining the reference internal impedance of a battery, the reference internal impedance varies (usually increases) with a discharge current, temperature, and battery aging. Such variations in internal impedance significantly affect the accuracy of estimating the battery's remaining capacity, discharge time, and state of health (SOH). Therefore, it is crucial for a battery management system to accurately estimate and predict battery's internal impedance.

Currently, known methods for determining the battery's internal impedance are typically conducted when the discharge current is in a stable state at a fixed level. However, this prior art method is challenging to apply to general applications, such as laptop computers, wherein the discharge current may undergo significant transient changes. As a result, the prior art techniques for determining battery internal impedance are limited in practical applications and are ineffective in coping with frequently changing discharge current conditions.

The main disadvantages of the prior art methods of determining battery internal impedance include:
First, inadequate response to transient variations in battery internal impedance: The prior art methods fail to provide sufficient determinations to cope with variations in battery internal impedance caused by changes in discharge current, temperature, and aging, resulting in insufficient accuracy in determining battery internal impedance.
Second, limited application range: The prior art methods of determining battery internal impedance typically require a stable discharge current, which is difficult to achieve in most practical applications (such as laptop computers) wherein the current frequently changes. Consequently, these prior arts cannot be widely applied to devices that operate under frequently changing current conditions.
Third, impact on estimation accuracy: Due to the inability of existing techniques to accurately determine battery internal impedance under varying current conditions, the accuracy of estimating the battery's remaining capacity, discharge time, and state of health is affected, thereby impacting the performance and reliability of the battery management system.

In summary, the prior art methods of determining battery internal impedance face several issues when addressing practical application needs, including insufficient accuracy in determining battery internal impedance, limited applicability, and a negative impact on battery performance estimation. These issues urgently require resolution through the development of new technologies.

In view of the above, to overcome the drawbacks in the prior art, the present invention proposes a method and system of determining a reference internal impedance of a battery. This invention not only improves the accuracy of sensing the battery's internal impedance but also allows for determining the reference internal impedance of a battery under transient conditions, thereby enhancing the efficiency of measuring the reference internal impedance.

### SUMMARY OF THE INVENTION

From one perspective, the present invention provides a method of determining a reference internal impedance of a battery, comprising: step (a) during a sensing period, sensing a battery voltage of a battery, a battery current flowing through the battery, and a battery temperature to obtain a sensing result, thereby determining a depth of discharge (DOD); step (b) in step (a), comparing the sensing result with a predetermined threshold to determine whether to accept the sensing result; step (c) when the sensing result is accepted, calculating a corresponding battery internal impedance based on the sensing result and the depth of discharge; step (d) performing regression analysis on the battery internal impedance and a plurality of previous battery internal impedances to obtain a moving average battery internal impedance corresponding to the depth of discharge; and step (e) calculating a corresponding reference battery internal impedance based on the moving average battery internal impedance.

In one embodiment, the method of determining a reference internal impedance of a battery further comprises: step (f) selecting the sensing period during a discharge period, determining whether the battery voltage is higher than an end of discharge voltage (EDV), and terminating the discharge period when the battery voltage is not higher than the end of discharge voltage.

In one embodiment, the method of determining a reference internal impedance of a battery further comprises: step (g) in step (b), when the sensing result is not accepted and is excluded, performing step (a) again in the next sensing period.

In one embodiment, step (c) includes: calculating the battery internal impedance based on the battery voltage, the battery current, and an open circuit voltage (OCV) corresponding to the depth of discharge.

In one embodiment, the plural previous battery internal impedances include a plurality of battery internal impedances prior to the sensing period or a plurality of moving average battery internal impedances prior to the sensing period.

In one embodiment, the regression analysis includes a first-order linear regression analysis or a second-order linear regression analysis.

In one embodiment, step (e) includes: calculating the corresponding reference battery internal impedance based on the moving average battery internal impedance, the battery current, and the battery temperature.

In one embodiment, the method of determining a reference internal impedance of a battery further comprises: (h) at the end of the sensing period, determining the next sensing period based on the open circuit voltage and the depth of discharge, to repeatedly perform step (a) and thereby determine a sensing frequency, wherein the sensing frequency is inversely proportional to the sensing period.

In one embodiment, a length of time of the next sensing period is inversely related to an absolute value of a slope between the open circuit voltage and the depth of discharge.

In one embodiment, the sensing period does not exclude a transient condition.

In one embodiment, step (b) includes: using the battery voltage as the sensing result and an open circuit voltage (OCV) corresponding thereto as the predetermined threshold, and determining to accept the sensing result when the battery voltage is not higher than the corresponding open circuit voltage; and/or using the battery current as the sensing result and a current lower limit as the predetermined threshold, and determining to accept the sensing result when the battery current is not lower than the current lower limit.

In one embodiment, the current lower limit is 1/10 of a 1 C discharge current of the battery.

From another perspective, the present invention provides a system of determining a reference internal impedance of a battery, comprising: a sensing unit for sensing, during a sensing period, a battery voltage of a battery, a battery current flowing through the battery, and a battery temperature of the battery to obtain a sensing result of the battery; and a control unit for comparing the sensing result with a predetermined threshold to determine whether to accept the sensing result, and when the sensing result is accepted, obtaining a depth of discharge (DOD) based on the sensing result, then calculating a corresponding battery internal impedance, performing a regression analysis on the battery internal impedance and a plurality of previous battery internal impedances to obtain a moving average battery internal impedance corresponding to the depth of discharge, and calculating a corresponding reference battery internal impedance based on the moving average battery internal impedance.

In one embodiment, the system of determining a reference internal impedance of a battery further comprises: a volatile memory unit for storing the battery internal impedance and the plural previous battery internal impedances; and a non-volatile memory unit for storing the reference battery internal impedance.

In one embodiment, the control unit selects the sensing period during a discharge period, determines whether the battery voltage is higher than an end of discharge voltage (EDV), and terminates the discharge period when the battery voltage is not higher than the end of discharge voltage.

In one embodiment, when the sensing result is not accepted and is excluded, the sensing unit senses the battery voltage, the battery current, and the battery temperature again during the next sensing period to obtain the next sensing result.

In one embodiment, the control unit calculates the battery internal impedance based on the battery voltage, the battery current, and an open circuit voltage (OCV) corresponding to the depth of discharge.

In one embodiment, the control unit calculates the corresponding reference battery internal impedance based on the moving average battery internal impedance, the battery current, and the battery temperature.

In one embodiment, at the end of the sensing period, the control unit determines the next sensing period based on the open circuit voltage and the depth of discharge to repeat the sensing period, thereby determining a sensing frequency, wherein the sensing frequency is inversely proportional to the sensing period.

The present invention has at least the following advantages over the prior art:
First, accurate internal impedance determination: The present invention proposes a new method that can accurately detect the internal impedance of the battery through regression filter analysis of the measured and stored data in memory, even when the discharge current varies. Unlike prior art that requires a stable discharge current for accurate measurement, the present invention overcomes this limitation, adapting to applications with frequently changing current, such as laptop computers, thereby significantly improving the accuracy of impedance determination.
Second, adaptive measurement timing interval: The present invention provides an adaptive timing interval for measuring the battery's internal impedance to improve accuracy and save energy. This means the system can automatically adjust the measurement frequency according to actual needs, avoiding unnecessary frequent measurements, thereby extending battery life and improving energy efficiency; and increase the measurement frequency when the related parameters change dramatically, to enhance measurement accuracy. This makes the invention more practical and efficient in a battery management system than prior arts that only measure at fixed intervals.

In summary, the present invention not only provides accurate battery internal impedance determination under varying current conditions but also effectively conserves power and improves accuracy through adaptive measurement intervals, overcoming the shortcomings of prior art in practical applications and significantly enhancing the performance and reliability of battery management systems.

The objectives, technical details, features, and effects of the present invention will be better understood with regard to the detailed description of the embodiments below, with reference to the attached drawings.

### BRIEF DESCRIPTION OF THE DRAWINGS

FIG. 1 is a block diagram of a module for the method of determining a reference internal impedance of a battery according to one embodiment of the present invention.

FIG. 2 is a flowchart illustrating the operation of the method of determining a reference internal impedance of a battery according to one embodiment of the present invention.

FIGS. 3A and 3B are flowcharts illustrating the operation of the method of determining a reference internal impedance of a battery according to another embodiment of the present invention.

FIG. 4A shows a schematic diagram of a lookup table relationship between OCV (open circuit voltage) and DOD (depth of discharge) in one embodiment of the present invention.

FIG. 4B shows a schematic diagram of a partial view corresponding to FIG. 4A, illustrating the relationship between the OCV and DOD lookup table and the battery internal impedance calculated during plural sensing periods, according to one embodiment of the present invention.

FIG. 4C shows a schematic diagram illustrating the regression analysis performed on the battery internal impedance and plural previous battery internal impedances according to one embodiment of the present invention.

FIG. 4D shows a schematic diagram illustrating the relationship between the old reference battery internal impedance and the updated reference battery internal impedance corresponding to DOD before and after implementing the method of determining a reference internal impedance of a battery, according to one embodiment of the present invention.

### DESCRIPTION OF THE PREFERRED EMBODIMENTS

The drawings as referred to throughout the description of the present invention are for illustration only, to show the interrelations between the circuits and the signal waveforms, but not drawn according to actual scale of circuit sizes and signal amplitudes and frequencies.

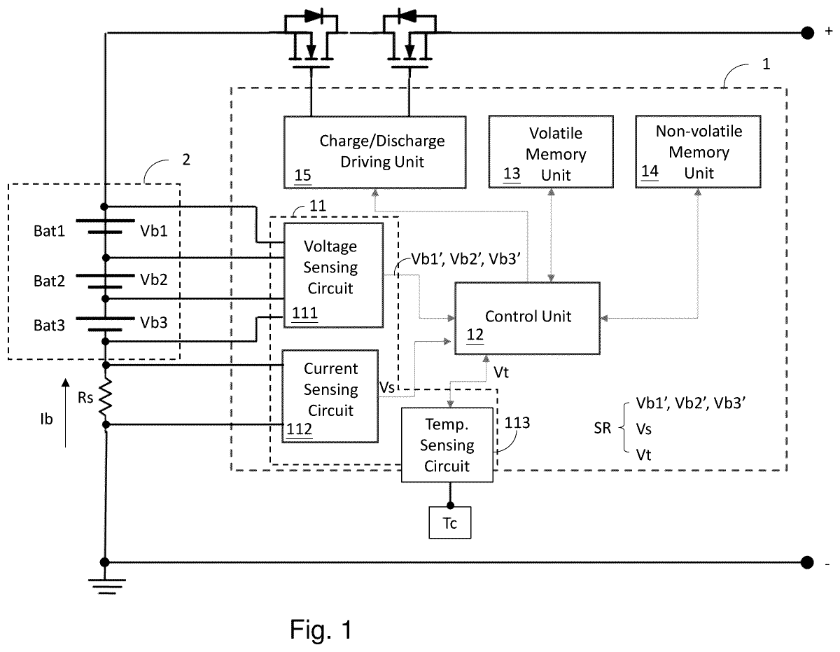

Referring to FIG. 1, FIG. 1 is a block diagram of a system 1 for determining a reference internal impedance of a battery according to one embodiment of the present invention. As shown in FIG. 1, the system 1 for determining a reference internal impedance of a battery includes a sensing unit 11 and a control unit 12. In this embodiment, the system 1 further comprises a volatile memory unit 13, a non-volatile memory unit 14, and a charge/discharge driving unit 15. The sensing unit 11 may include, for example, a voltage sensing circuit 111, a current sensing circuit 112, and a temperature sensing circuit 113. It should be noted that the reference internal impedance refers to the internal impedance of the battery under specific temperature and load conditions, which is stored in the non-volatile memory unit 14 and can be updated for use as a reference in calculating battery characteristic parameters such as Relative State Of Charge (RSOC) or Full Charge Capacity (FCC).

In this embodiment, the voltage sensing circuit 111 is coupled to a battery pack 2 and is used to sense the battery voltage Vb1, Vb2, Vb3 of each of the batteries Bat1, Bat2, Bat3, which are connected in series in the battery pack 2, thereby generating battery voltage sensing signals Vb1′, Vb2′, Vb3′. The battery voltage sensing signals Vb1′, Vb2′, Vb3′ may be stored in the volatile memory unit 13 for calculation or transmission. The battery current sensing signals and battery temperature sensing signals, as described later, can also be stored in the volatile memory unit 13 and will not be repeated here. In some embodiments, the voltage sensing circuit 111 may include, but is not limited to, an analog-to-digital converter (ADC) and a multiplexer (MUX) to achieve the voltage sensing function, where the structure and function of the ADC and MUX are well known to those skilled in the art of the present invention and will not be further described.

The current sensing circuit 112 is coupled with a sensing resistor Rs in series with the battery pack 2 to sense the battery current Ib flowing through the batteries Bat1, Bat2, Bat3 and to generate a battery current sensing signal Vs. The temperature sensing circuit 113 is coupled with a temperature-sensitive element Tc to sense the battery temperature and generate a battery temperature sensing signal Vt. The battery voltage sensing signals Vb1′, Vb2′, Vb3′, the battery current sensing signal Vs, and the battery temperature sensing signal Vt together constitute the sensing result SR.

In this embodiment, the sensing unit 11 is used to sense the battery voltage Vb1, Vb2, Vb3 of each battery Bat1, Bat2, Bat3, the battery current Ib flowing through the batteries Bat1, Bat2, Bat3, and the battery temperature of the batteries Bat1, Bat2, Bat3 during the sensing period to obtain the sensing result SR of the batteries Bat1, Bat2, Bat3. It should be noted that in this embodiment, each sensing result SR corresponds to only one battery Bat1, Bat2, or Bat3, and the subsequently obtained corresponding battery internal impedance and standard battery internal impedance also correspond to only one battery Bat1, Bat2, or Bat3. In other words, each battery Bat1, Bat2, or Bat3 has its respective corresponding battery internal impedance and standard battery internal impedance, as well as its corresponding lookup table relationship between the open circuit voltage (OCV) and the depth of discharge (DOD).

The control unit 12 is used to compare the sensing result SR with a predetermined threshold to determine whether to accept the sensing result SR, and when the sensing result SR is accepted, obtain the corresponding depth of discharge (DOD) based on the sensing result SR, then calculate the corresponding battery internal impedance, and perform regression analysis on the battery internal impedance and plural previous battery internal impedances to obtain a moving average battery internal impedance corresponding to the depth of discharge, and calculate the corresponding reference battery internal impedance based on the moving average battery internal impedance.

In one embodiment, the battery voltage Vb1, Vb2, Vb3 (or the corresponding battery voltage sensing signals Vb1′, Vb2′, Vb3′) are used as the sensing result SR, and the corresponding open circuit voltage (OCV) is used as the predetermined threshold. The control unit 12 determines to accept the sensing result SR when the battery voltage Vb1, Vb2, Vb3 is not higher than the corresponding open circuit voltage; and/or the battery current Ib is used as the sensing result SR, and a current lower limit is used as the predetermined threshold, and the control unit 12 determines to accept the sensing result when the battery current Ib is not lower than the current lower limit. This means that, according to the present invention, sensing results where the battery voltage is higher than the corresponding open circuit voltage (indicating an unreasonable phenomenon where the battery current is negative) and/or the battery current is lower than the current lower limit (indicating the battery current is too low) can be excluded.

In one embodiment, the current lower limit is 1/10 of a 1 C discharge current of the battery Bat1, Bat2, or Bat3. It should be noted that the 1 C discharge current refers to the current corresponding to the battery being discharged at 1 C. For example, a battery with a rated capacity of 200 mAh has a 1 C discharge current of 200 mA. This is well known to those skilled in the art and will not be further described here.

In one embodiment, when the sensing result SR is accepted, the control unit 12 uses lookup tables or built-in functions stored in the non-volatile memory unit 14 to obtain the corresponding depth of discharge (DOD) by looking up the battery voltage sensing signal Vb1′, battery current sensing signal Vs, and/or battery temperature sensing signal Vt or plugging them into built-in functions; then, based on the lookup table of open circuit voltage (OCV) and depth of discharge (DOD) stored in the non-volatile memory unit 14, the corresponding open circuit voltage (OCV) is obtained. Further, for example, the battery internal impedance is calculated based on the voltage difference between the open circuit voltage (OCV) and the battery voltage Vb1, divided by the battery current Ib.

The volatile memory unit 13 is coupled with the control unit 12 for storing the battery internal impedance and plural previous battery internal impedances. The non-volatile memory unit 14 is coupled with the control unit 12 for storing the reference battery internal impedance. The non-volatile memory unit 14 can also store the aforementioned lookup tables, built-in functions, lookup tables of open circuit voltage (OCV), and depth of discharge (DOD), etc. The charge/discharge driving unit 15 is coupled between the control unit 12 and the power switches SWC, SWD, for driving and operating the power switches SWC, SWD to charge/discharge the battery pack 2 according to the control signals from the control unit 12. This is well known to those skilled in the art and will not be further described here.

In one embodiment, the control unit 12 selects the sensing period during the discharge period, determines whether the battery voltage is higher than the end of discharge voltage (EDV), and terminates the discharge period when the battery voltage is not higher than the end of discharge voltage. At the same time, it also terminates the sensing period and stops determining the reference internal impedance of the battery. In one embodiment, the steps performed during the sensing period are all conducted during the discharge period of the battery.

In one embodiment, when the sensing result SR is not accepted and is excluded, the sensing unit 11 waits for the end of the sensing period, and during the next sensing period, re-senses the battery voltage Vb1, Vb2, Vb3, the battery current Ib, and the battery temperature to obtain the next sensing result SR.

In one embodiment, the control unit 12 calculates the battery internal impedance based on the battery voltage Vb1, Vb2, Vb3, the battery current Ib, and the open circuit voltage (OCV) corresponding to the depth of discharge (DOD).

In one embodiment, plural previous battery internal impedances include plural previous battery internal impedances prior to the sensing period or plural previous moving average battery internal impedances prior to the sensing period.

In one embodiment, the regression analysis includes a first-order linear regression analysis or a second-order linear regression analysis.

In one embodiment, the control unit 12 calculates the corresponding reference battery internal impedance based on the moving average battery internal impedance, the battery current Ib, and the battery temperature. It should be noted that, in this embodiment, the reference battery internal impedance is, for example, the internal impedance of the battery at 25 degrees Celsius with no load (open-circuit battery).

In one embodiment, at the end of the sensing period, the control unit determines the next sensing period based on the open circuit voltage and the depth of discharge, to repeat the sensing period and thereby determine the sensing frequency, wherein the sensing frequency is inversely proportional to the sensing period.

In one embodiment, the length of time of a sensing period is inversely related to the absolute value of the slope between the open circuit voltage and the depth of discharge. In other words, according to the present invention, the greater the absolute value of the slope between the open circuit voltage (OCV) and the depth of discharge (DOD), which indicates a greater change in the open circuit voltage, the shorter the period for the adaptive battery internal impedance determination interval (i.e., the sensing period) in order to improve accuracy and save energy. For example, the length of time of the sensing period is inversely proportional to the absolute value of the slope between the open circuit voltage and the depth of discharge. This means that the system can automatically adjust the measurement frequency based on the change in the open circuit voltage relative to the depth of discharge, avoiding unnecessary frequent measurements, thereby extending life and improving energy efficiency; and increasing the sensing frequency when the open circuit voltage changes significantly to improve the accuracy of the reference battery internal impedance.

In one embodiment, the sensing period does not exclude a transient condition. This means that, according to the present invention, it is possible to accurately detect the battery internal impedance and calculate a more accurate reference battery internal impedance under conditions where the discharge current (the battery current during discharge) fluctuates relatively greatly, through regression filter analysis of the measured data stored in the memory, without deliberately avoiding transient conditions, thereby improving the efficiency and accuracy of determining the reference battery internal impedance.

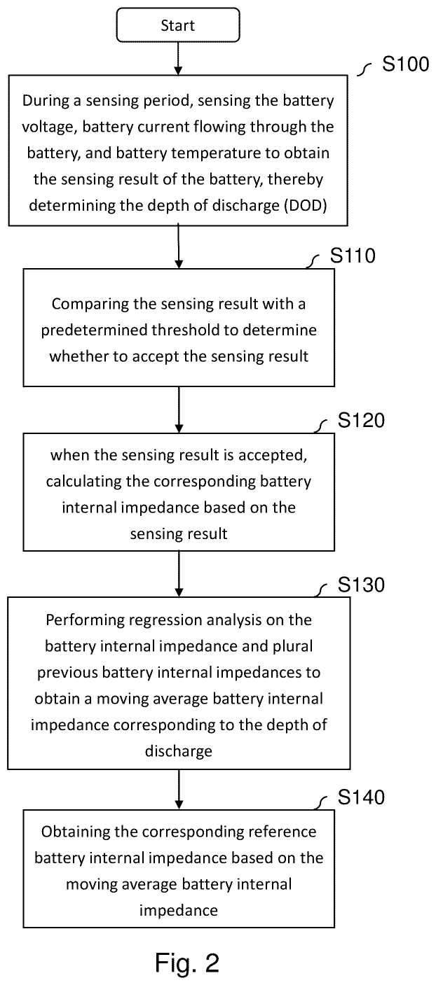

Referring to FIG. 2, FIG. 2 is a flowchart illustrating the method of determining a reference internal impedance of a battery according to one embodiment of the present invention. As shown in FIG. 2, the method includes:
Step S100: During a sensing period, sensing the battery voltage, battery current flowing through the battery, and battery temperature to obtain the sensing result of the battery, thereby determining the depth of discharge (DOD);
Step S110: Following step S100, comparing the sensing result with a predetermined threshold to determine whether to accept the sensing result;
Step S120: Following step S110, when the sensing result is accepted, calculating the corresponding battery internal impedance based on the sensing result;
Step S130: Following step S120, performing regression analysis on the battery internal impedance and plural previous battery internal impedances to obtain a moving average battery internal impedance corresponding to the depth of discharge; and
Step S140: Following step S130, obtaining the corresponding reference battery internal impedance based on the moving average battery internal impedance.

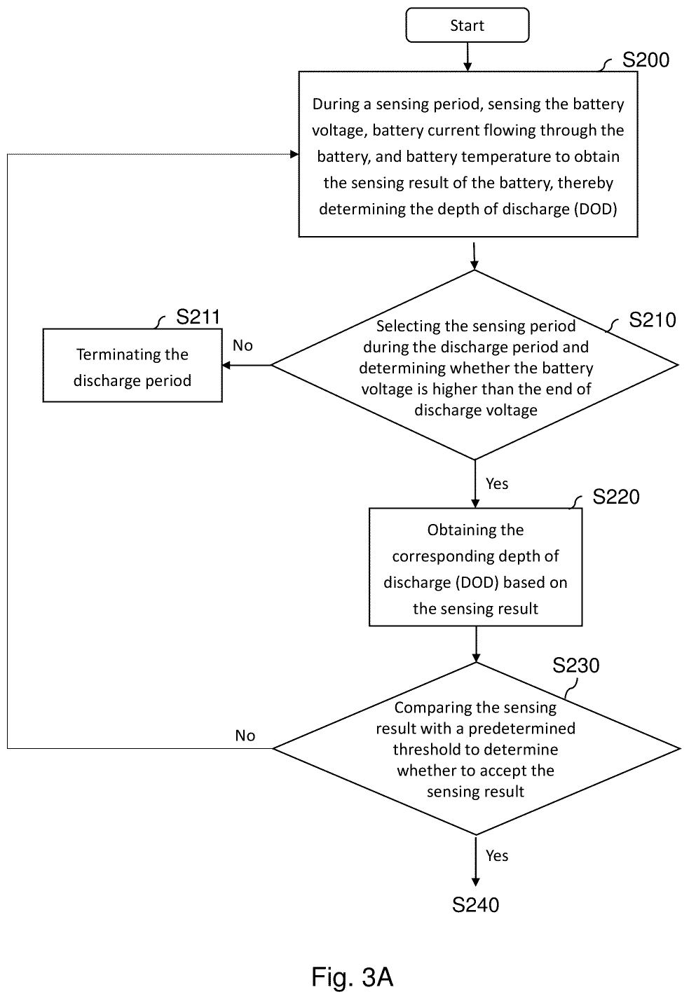

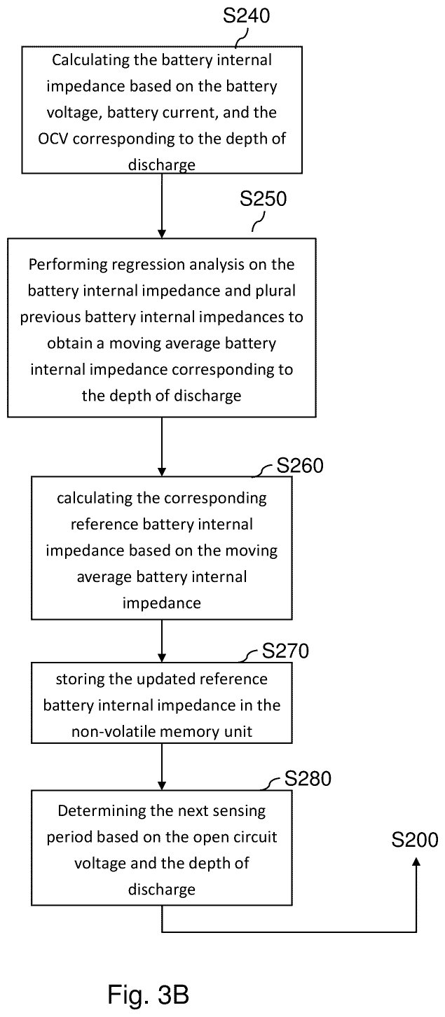

Referring to FIGS. 3A and 3B, FIGS. 3A and 3B are flowcharts illustrating the method of determining a reference internal impedance of a battery according to another embodiment of the present invention. As shown in FIGS. 3A and 3B, the method includes:
Step S200: During a sensing period, sensing the battery voltage, battery current flowing through the battery, and battery temperature to obtain the sensing result of the battery, thereby determining the depth of discharge (DOD);
Step S210: Selecting the sensing period during the discharge period and determining whether the battery voltage is higher than the end of discharge voltage; if so, proceed to step S220; if not, proceed to step S211;
Step S211: When the sensing result is not accepted and is excluded, terminate the discharge period, and also terminate the sensing period to stop determining the reference internal impedance of the battery.
Step S220: When the sensing result is accepted, obtain the corresponding depth of discharge (DOD) based on the sensing result;
Step S230: Compare the sensing result with a predetermined threshold to determine whether to accept the sensing result; if so, proceed to step S240; if not, proceed to step S200;
Step S240: Calculate the battery internal impedance based on the battery voltage, battery current, and the OCV corresponding to the depth of discharge;
Step S250: Following step S240, perform regression analysis on the battery internal impedance and plural previous battery internal impedances to obtain a moving average battery internal impedance corresponding to the depth of discharge;
Step S260: Following step S250, calculate the corresponding reference battery internal impedance based on the moving average battery internal impedance;
Step S270: Following step S260, store the updated reference battery internal impedance in the non-volatile memory unit;
Step S280: Following step S270, determine the next sensing period based on the open circuit voltage and the depth of discharge, and return to step S200, thereby determining a sensing frequency, wherein the sensing frequency is inversely proportional to the sensing period.

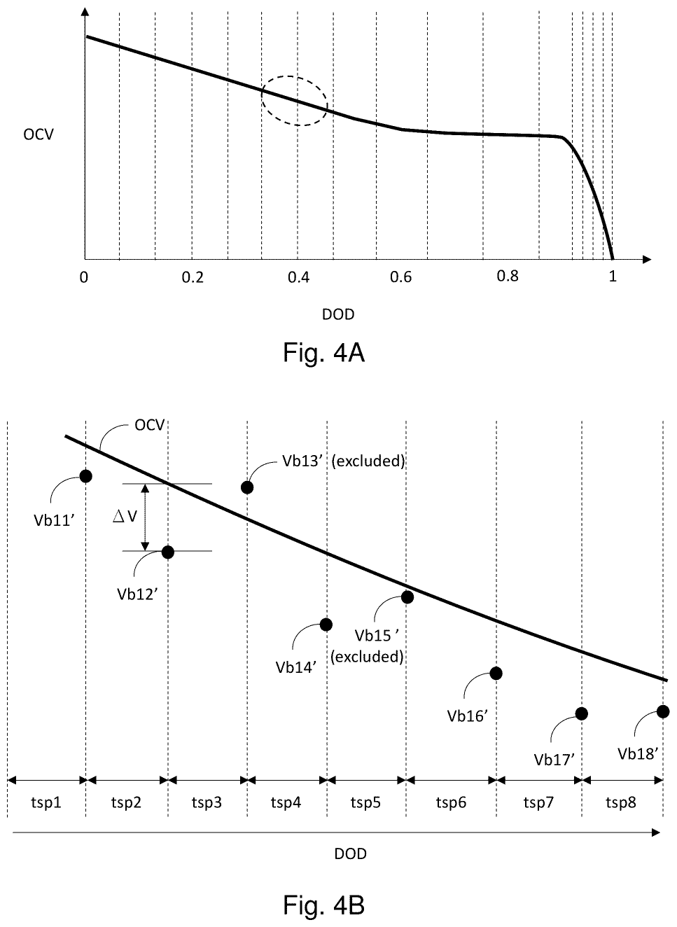

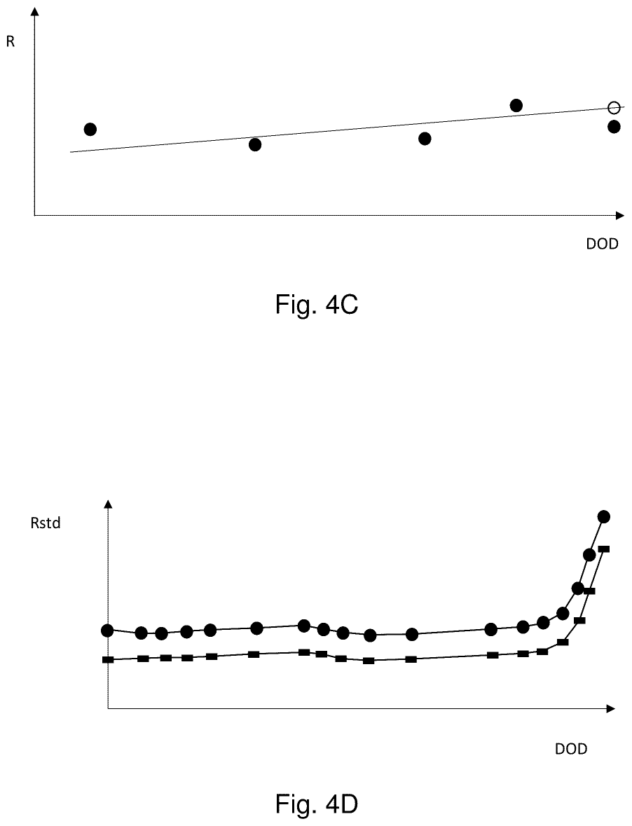

FIG. 4A shows a schematic diagram of a lookup table relationship between OCV (open circuit voltage) and DOD (depth of discharge) in one embodiment of the present invention. As shown in FIG. 4A, the horizontal axis represents the depth of discharge (DOD), and the vertical axis represents the open circuit voltage (OCV). This lookup table relationship between OCV and DOD may be stored in the non-volatile memory unit 140. During the sensing period, the control unit 12, based on the sensing result SR, refers to the lookup table relationship or built-in functions stored in the non-volatile memory unit 140 to obtain the corresponding DOD; then, according to the lookup table relationship between OCV and DOD shown in FIG. 4A, determines the interval to be calculated, as indicated by the elliptical dashed box in FIG. 4A.

Moreover, it should be noted that the plural dashed vertical lines in FIG. 4A illustrate the absolute value of the slope relationship of OCV corresponding to DOD, indicating the sensing frequency, which is the inverse relationship of the sensing period corresponding to DOD; when the dashed vertical lines are denser, it means the absolute value of the slope of OCV corresponding to DOD is greater, and the change in OCV corresponding to DOD is larger, suggesting an adaptive adjustment to increase the number of times for determining the reference internal impedance of the battery to improve accuracy; when the dashed vertical lines are sparser, it means the absolute value of the slope of OCV corresponding to DOD is smaller, and the change in OCV corresponding to DOD is smaller, suggesting an adaptive adjustment to reduce the number of times for determining the reference internal impedance of the battery to save energy.

FIG. 4B shows a schematic diagram of a partial view corresponding to FIG. 4A (i.e., the area indicated by the elliptical dashed box in FIG. 4A) illustrating the relationship between the lookup table of OCV corresponding to DOD and the battery internal impedance calculated during plural sensing periods according to one embodiment of the present invention. As shown in FIG. 4B, during plural sensing periods tsp1-tsp8, the corresponding depth of discharge (DOD) is obtained based on the sensing result SR for each sensing period tsp1-tsp8, and then the corresponding battery internal impedance is calculated by comparing the battery voltage (as indicated by the solid circles representing battery voltage sensing signals Vb11′-Vb18′) in each sensing period tsp1-tsp8. For example, the battery internal impedance is calculated based on the voltage difference AV between the open circuit voltage (OCV) and the battery voltage (indicated by the battery voltage sensing signals Vb11′-Vb18′), divided by the battery current Ib.

Referring further to FIG. 4B, the battery voltage indicated by the battery voltage sensing signal Vb13′ being higher than the corresponding open circuit voltage indicates an unreasonable phenomenon where the battery current Ib is negative, and the battery voltage indicated by the battery voltage sensing signal Vb15′ being lower than the current lower limit excludes the sensing results of sensing periods tsp3 and tsp5.

For example, after excluding the sensing results of sensing periods tsp3 and tsp5, the battery internal impedance corresponding to each depth of discharge (DOD) is calculated using the battery voltage sensing signals Vb11′, Vb12′, Vb14′, Vb16′-Vb18′ in the sensing results SR of the sensing periods tsp1, tsp2, tsp4, tsp6-tsp8 and the corresponding open circuit voltage (OCV) corresponding to the depth of discharge (DOD). Then, regression analysis is performed on the battery internal impedance corresponding to these sensing periods tsp1, tsp2, tsp4, tsp6-tsp8 to obtain a moving average battery internal impedance corresponding to the depth of discharge of sensing period tsp8, and further, the reference battery internal impedance corresponding to the depth of discharge of sensing period tsp8 is calculated based on the obtained moving average battery internal impedance. This reference battery internal impedance is then stored in the non-volatile memory unit 13 to update the old reference battery internal impedance.

FIG. 4C shows a schematic diagram of regression analysis performed on the battery internal impedance and plural previous battery internal impedances according to one embodiment of the present invention. As shown in FIG. 4C, after obtaining plural battery internal impedances R corresponding to different DODs, regression analysis is performed on these battery internal impedances R, such as a first-order linear regression analysis, resulting in a first-order linear relationship between the battery internal impedance R and DOD, as indicated by the black solid line in FIG. 4C. The subsequent moving average battery internal impedance corresponding to DOD, as indicated by the hollow circles in FIG. 4C, is substituted into the function for the reference battery internal impedance to calculate the corresponding reference battery internal impedance for the DOD.

FIG. 4D shows a schematic diagram of the relationship between the old reference battery internal impedance Rstd and the updated reference battery internal impedance Rstd corresponding to DOD before and after implementing the method of determining the reference internal impedance Rstd of the battery, according to one embodiment of the present invention. With the discharge current, temperature, and aging of the battery, the reference battery internal impedance Rstd increases. The reference battery internal impedance Rstd before implementing the method of determining the reference internal impedance Rstd of the battery is indicated by the plural solid rectangles in FIG. 4D, while the reference battery internal impedance Rstd after implementing the method according to the present invention is indicated by the plural solid circles in FIG. 4D. According to the present invention, not only can accurate determination of battery internal impedance be provided under varying current conditions, but also effective power conservation and improved accuracy can be achieved through adaptive measurement intervals, overcoming the shortcomings of the prior art in practical applications and significantly enhancing the performance and reliability of battery management systems.

The present invention has been described in considerable detail with reference to certain preferred embodiments thereof. It should be understood that the description is for illustrative purpose, not for limiting the broadest scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. For example, to perform an action “according to” a certain signal as described in the context of the present invention is not limited to performing an action strictly according to the signal itself, but can be performing an action according to a converted form or a scaled-up or down form of the signal, i.e., the signal can be processed by a voltage-to-current conversion, a current-to-voltage conversion, and/or a ratio conversion, etc. before an action is performed. It is not limited for each of the embodiments described hereinbefore to be used alone; under the spirit of the present invention, two or more of the embodiments described hereinbefore can be used in combination. For example, two or more of the embodiments can be used together, or, a part of one embodiment can be used to replace a corresponding part of another embodiment. In view of the foregoing, the spirit of the present invention should cover all such and other modifications and variations, which should be interpreted to fall within the scope the following claims and their equivalents.

What is claimed is:

1. A method of determining a reference internal impedance of a battery, comprising:
step (a), during a sensing period, sensing a battery voltage, a battery current flowing through the battery, and a battery temperature to obtain a sensing result, thereby determining a depth of discharge (DOD);
step (b), in step (a), comparing the sensing result with a predetermined threshold to determine whether to accept the sensing result;
step (c), when the sensing result is accepted, calculating a corresponding battery internal impedance based on the sensing result and the depth of discharge;
step (d), performing regression analysis on the battery internal impedance and a plurality of previous battery internal impedances to obtain a moving average battery internal impedance corresponding to the depth of discharge; and
step (e), calculating a corresponding reference battery internal impedance based on the moving average battery internal impedance.

2. The method of claim 1, further comprising:
step (f), selecting the sensing period during a discharge period, and determining whether the battery voltage is higher than an end of discharge voltage (EDV), and terminating the discharge period when the battery voltage is not higher than the end of discharge voltage.

3. The method of claim 1, further comprising:
step (g), in step (b), when the sensing result is not accepted and is excluded, performing step (a) again in the next sensing period.

4. The method of claim 1, wherein step (c) includes: calculating the battery internal impedance based on the battery voltage, the battery current, and an open circuit voltage (OCV) corresponding to the depth of discharge.

5. The method of claim 1, wherein the plural previous battery internal impedances include plural battery internal impedances prior to the sensing period or a plurality of moving average battery internal impedances prior to the sensing period.

6. The method of claim 1, wherein the regression analysis includes a first-order linear regression analysis or a second-order linear regression analysis.

7. The method of claim 1, wherein step (e) includes: calculating the corresponding reference battery internal impedance based on the moving average battery internal impedance, the battery current, and the battery temperature.

8. The method of claim 4, further comprising:
step (h), at the end of the sensing period, determining the next sensing period based on the open circuit voltage and the depth of discharge, to repeatedly perform step (a) and thereby determine a sensing frequency, wherein the sensing frequency is inversely proportional to the sensing period.

9. The method of claim 8, wherein a length of time of the next sensing period is inversely related to an absolute value of a slope between the open circuit voltage and the depth of discharge.

10. The method of claim 1, wherein the sensing period does not exclude a transient condition.

11. The method of claim 1, wherein step (b) includes: using the battery voltage as the sensing result and an open circuit voltage (OCV) corresponding thereto as the predetermined threshold, and determining to accept the sensing result when the battery voltage is not higher than the corresponding open circuit voltage; and/or using the battery current as the sensing result and a current lower limit as the predetermined threshold, and determining to accept the sensing result when the battery current is not lower than the current lower limit.

12. The method of claim 11, wherein the current lower limit is 1/10 of a 1 C discharge current of the battery.

13. A system of determining a reference internal impedance of a battery, comprising:
a sensing unit, for sensing, during a sensing period, a battery voltage of a battery, a battery current flowing through the battery, and a battery temperature of the battery to obtain a sensing result of the battery; and
a control unit, for comparing the sensing result with a predetermined threshold to determine whether to accept the sensing result, and when the sensing result is accepted, obtaining a depth of discharge (DOD) based on the sensing result, then calculating a corresponding battery internal impedance, performing a regression analysis on the battery internal impedance and a plurality of previous battery internal impedances to obtain a moving average battery internal impedance corresponding to the depth of discharge, and calculating a corresponding reference battery internal impedance based on the moving average battery internal impedance.

14. The system of claim 13, further comprising:
a volatile memory unit for storing the battery internal impedance and the plural previous battery internal impedances; and
a non-volatile memory unit for storing the reference battery internal impedance.

15. The system of claim 13, wherein the control unit selects the sensing period during a discharge period, and determines whether the battery voltage is higher than an end of discharge voltage (EDV), and terminates the discharge period when the battery voltage is not higher than the end of discharge voltage.

16. The system of claim 13, wherein when the sensing result is not accepted and is excluded, the sensing unit senses the battery voltage, the battery current, and the battery temperature again during the next sensing period to obtain the next sensing result.

17. The system of claim 13, wherein the control unit calculates the battery internal impedance based on the battery voltage, the battery current, and an open circuit voltage (OCV) corresponding to the depth of discharge.

18. The system of claim 13, wherein the plural previous battery internal impedances include a plurality of battery internal impedances prior to the sensing period or a plurality of moving average battery internal impedances prior to the sensing period.

19. The system of claim 13, wherein the regression analysis includes a first-order linear regression analysis or a second-order linear regression analysis.

20. The system of claim 13, wherein the control unit calculates the corresponding reference battery internal impedance based on the moving average battery internal impedance, the battery current, and the battery temperature.

21. The system of claim 17, wherein at the end of the sensing period, the control unit determines the next sensing period based on the open circuit voltage and the depth of discharge to repeat the sensing period, thereby determining a sensing frequency, wherein the sensing frequency is inversely proportional to the sensing period.

22. The system of claim 21, wherein a length of time of the next sensing period is inversely related to an absolute value of a slope between the open circuit voltage and the depth of discharge.

23. The system of claim 13, wherein the sensing period does not exclude a transient condition.

24. The system of claim 13, wherein using the battery voltage as the sensing result and an open circuit voltage (OCV) corresponding thereto as the predetermined threshold, the control unit determines to accept the sensing result when the battery voltage is not higher than the corresponding open circuit voltage; and/or using the battery current as the sensing result and a current lower limit as the predetermined threshold, the control unit determines to accept the sensing result when the battery current is not lower than the current lower limit.

25. The system of claim 24, wherein the current lower limit is 1/10 of a 1 C discharge current of the battery.
